(19) United States
(12) Patent Application Publication
(10) Pub. No.: US 2006/0086020 A1
(43) Pub. Date: Apr. 27, 2006

(54) Multi-mode flat-panel light-emitting sign

(75) Inventors: David R. Strip, Albuquerque, NM (US); Ronald S. Cok, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 10/974,617

(22) Filed: Oct. 27, 2004

(51) Int. Cl. G09F 13/22

(52) U.S. Cl. 40/544

(57) ABSTRACT

A multi-mode flat-panel light-emitting sign having a substrate, a plurality of thin-film light-emitting structures located on the substrate, each structure comprised of an anode, a light-emitting layer, and a cathode wherein light-emitting layer has a pattern for providing a visual indicia when the light-emitting structure is activated, the anode and the cathode of each thin-film emitting structure being continuous over the substrate, and a cover provided over the plurality of thin-film light-emitting structures.

### FIELD OF THE INVENTION

The present invention relates to the field of flat-panel illuminating sources and more particularly to informational signage.

### BACKGROUND OF THE INVENTION

Informational signage is so common in the built environment that we often hardly notice it. A very common example is the humble exit sign that hangs above doorways and loiters in halls. There are many situations where it is desirable to provide multiple messages, preferably in a small space, often for design considerations, but also for safety reasons as well. In parts of the United States, the exit sign should also say “SALIDA”, whereas in Canada, “SORTIE” is dictated by law. The common backlit and edge-lit designs utilized in the vast majority of these signs makes it impossible to provide two different messages in the same space. Instead, we often see either two signs, or a single sign with two lines of text. While it is possible to implement this functionality using programmable displays, this alternative is expensive, may fail to meet the reliability requirements for critical safety signs, and has relatively high power consumption, which leads to added costs for systems that are required to operate continuously in the face of power outages.

There is therefore a need for signage that is capable of presenting multiple pre-determined messages in the same space at different times.

### SUMMARY OF THE INVENTION

In accordance with one aspect of the present invention there is provided a multi-mode flat-panel light-emitting sign comprising:

a) a substrate;

b) a plurality of thin-film light-emitting structures located on the substrate, each structure comprised of an anode, a light-emitting layer, and a cathode wherein light-emitting layer has a pattern for providing a visual indicia when the light-emitting structure is activated, the anode and the cathode of each thin-film emitting structure being continuous over the substrate; and

c) a cover provided over the plurality of thin-film light-emitting structures.

In accordance with another aspect of the present invention there is provided a multi-mode flat-panel light-emitting sign comprising:

a) a substrate;

b) two thin-film light-emitting structures located on the substrate, each structure comprised of an anode, a light-emitting layer, and a cathode wherein either the anode and/or cathode has a continuous pattern for providing a visual indicia when the light-emitting structure is activated, the continuous pattern for each of the two thin-film light-emitting structures being electrically in common with each other, the thin-film light-emitting structures being continuous over the substrate; and

c) a cover provided over the two thin-film light-emitting structures.

### ADVANTAGES

The Multi-mode Flat-Panel Light-Emitting Sign allows multiple messages to be displayed in the same space, enabling attractive multi-lingual signs, for example. Alternatively, predetermined messages which need to change corresponding to external events or commands are accommodated in the space of a single sign.

These and other aspects, objects, features and advantages of the present invention will be more clearly understood and appreciated from a review of the following detailed description of the preferred embodiments and appended claims and by reference to the accompanying drawings.

### BRIEF DESCRIPTION OF THE DRAWINGS

In the detailed description of the preferred embodiments of the invention presented below, reference is made to the accompanying drawings in which:

FIG. 1 illustrates the layer structure of one embodiment of the invention;

FIG. 2 is an exploded view of a bi-lingual sign embodying the invention;

FIG. 3 illustrates an embodiment of the invention that permits two layers to convey more than two messages;

FIG. 4 illustrates the layer structure of an embodiment of the invention suited to produce four distinct messages; and

FIG. 5 is a table showing how to connect anodes and cathodes to reduce the contact count.

### DESCRIPTION OF THE INVENTION

Signs with multiple messages are common in everyday life. Examples include the ubiquitous Open/Closed signs in store windows, elevator direction and floor indicators, bi-lingual exit signs, and so on. There are numerous approaches to self-illuminating multiple message signs, each with one or more shortcomings. Probably the most common form of multiple message self-illuminating sign is comprised of a backlit patterned window, where each message has an individually controllable lamp. By selecting the lamp to light, the sign message is determined. Slightly less common would be an edge-lit variant in which the message is etched into a transmissive medium such as glass and each message is individually edge-lit by a lamp. While these approaches can be quite economical, each message requires a distinct area and is generally readable even when not illuminated. A second approach is to produce a series of neon lamps, one for each message. The lamps are stacked one in front of the next. The lamp corresponding to the desired message is provided with electrical current that causes it to glow. This approach eliminates the need to provide a distinct area for each message. This is achieved, however, at the cost of degraded readability. In addition, the sign becomes fairly thick and forming the glass for neon is a challenging and expensive process. Yet a third alternative is to display the message on a general-purpose, programmable pixellated display device. While this approach provides tremendous versatility in message selection, the versatility comes with added complexity and cost. In addition, unless the display pixels have a fine pitch, it is often not possible to select the font or other appearance characteristics of the message. Examples of this class of display include active- and passive-matrix emissive displays, be they made from LCD, LED, OLED, or other technology.

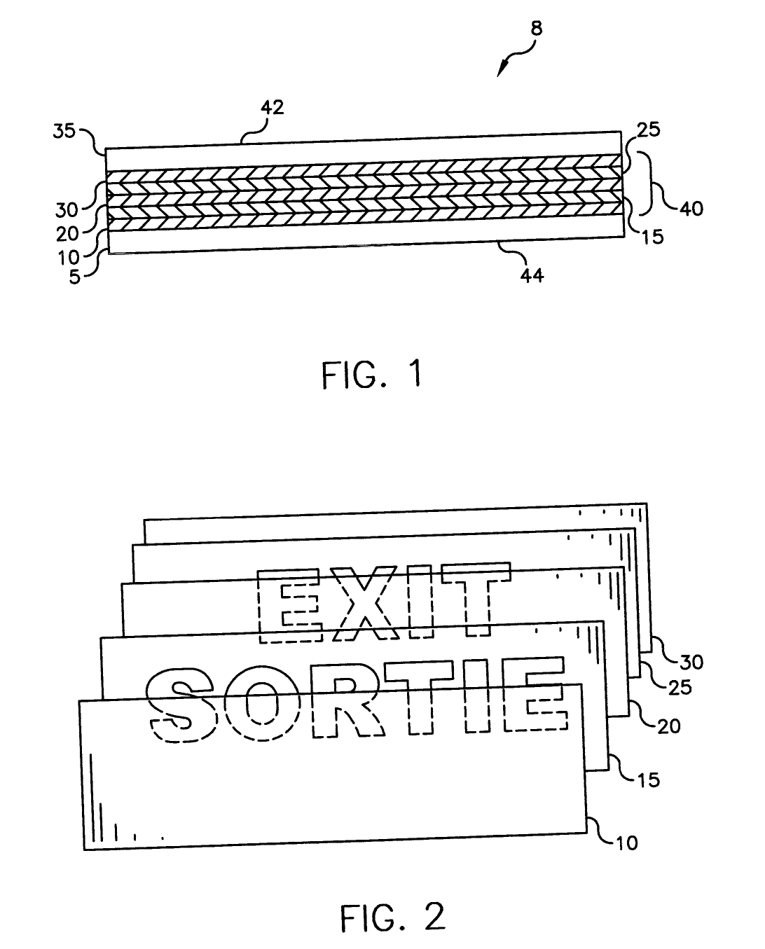

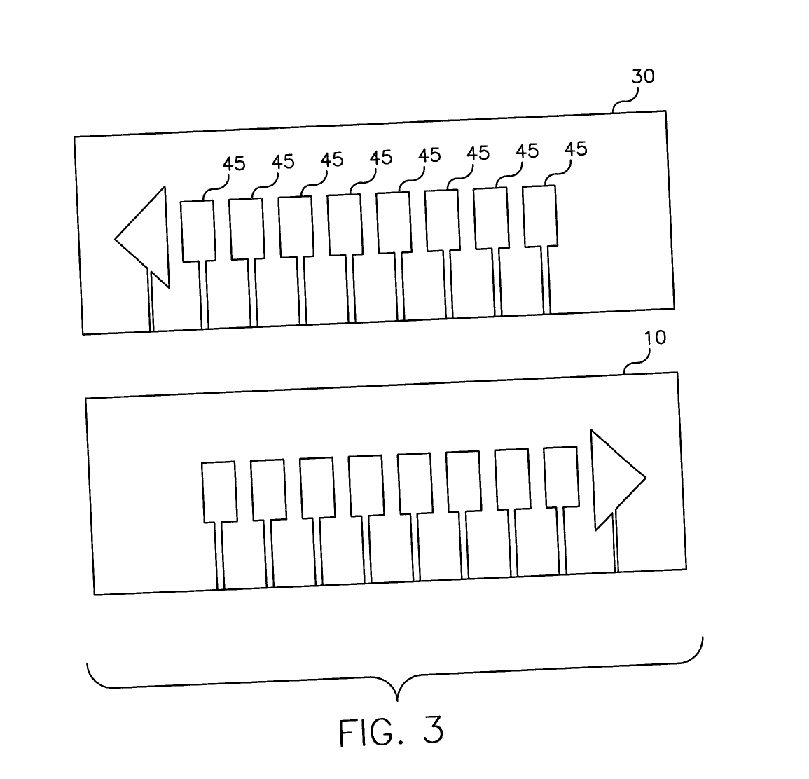

FIG. 1. depicts a basic embodiment of sign 8 made in accordance with the present invention utilizing organic light-emitting diode thin films as the emissive element. The sign 8 comprises a substrate 5 that is coated with a first anode layer 10, a first OLED layer 15, a transparent common cathode 20, a second OLED layer 25, a second anode 30 and finally a cover 35. The layers between the substrate 5 and the cover 35 will be referred to as a dual-mode stack 40. FIG. 2 shows a particularly simple embodiment of the invention. The first anode 10 and second anode 30 and the common cathode 20 are produced as uniform, unpatterned layers.

The first OLED layer 15 is patterned in the form of the first message and the second OLED layer 25 is patterned with the second message. When power is provided to the first anode 10 and the common cathode 20, the first message becomes visible. When power is provided to the second anode 30 and the common cathode 20, the second message becomes visible. When power is applied to both anodes using the common cathode as a ground, both messages are simultaneously visible.

Depending upon details of the manufacturing process, it may be desirable to pattern the first and second anode layers 10, 30 rather than the first and second OLED layers 15, 25. Alternatively, we can replace the common, unpatterned cathode 20 with a distinct patterned cathode for each message, which then allows us to utilize unpatterned anode and OLED layers. Another alternative is to interpose a patterned insulating layer between the anode and OLED layers or cathode and OLED layers. This allows us to produce unpatterned anode, cathode, and OLED layers, at the expense of a patterned insulating layer.

Regardless of whether the patterning for the message is in the anode, cathode, or OLED layer, it is possible to form the OLED layer from multiple emitter types such that distinct regions of the OLED layer emit in different colors, permitting a single message to contain multiple colors.

The cover 35 and substrate 5 may be made of transparent glass or may have reflective layers deposited on them. OLED layers are typically very thin and are also relatively transparent. Electrodes may be made of transparent materials, for example indium tin oxide or thin, transparent layers of metals such as silver and aluminum. Alternatively, electrodes may be reflective, for example made of thick metal layers. All these materials and techniques for their deposition are known in the art. In this way, light emission from either or both sides of the light-emitting sign 8 may be controlled.

The multiple message light-emitting sign 8 shown and described above emits light from both sides 42, 44 with the same message visible from either side, although one side will read as a mirror image. When the sign 8 is unpowered, it is transparent, becoming unobtrusive. We can replace the transparent common cathode with a reflective common cathode (or multiple cathodes). In this case, each side of the sign contains an independently controlled message. Yet another alternative is to make one of the anodes reflective, keeping a transparent cathode and one transparent anode. This configuration provides a sign in which all modes are visible from one side and invisible from the other.

FIG. 3 shows a pair of patterns for anode layers 10 and 30 that may be utilized in a multiple-message sign with unpatterned OLED layers and a common cathode layer. As shown in FIG. 3 the individual anode pattern elements 45 are extended to the edge of the substrate 5 so that they may be connected and powered individually. The individual connection to each of the anode pattern elements 45 allows these elements to be controlled independently of one another, allowing additional visual effects to be produced by the sign 8. In the example in FIG. 3, by illuminating the anode pattern elements 45 of one of the anode layers 10, 30 in sequence, we can produce the impression of a moving indicator. By depositing different colored emitting layers for OLED layer 10 and OLED layer 30, the two direction indicators will emit in different colors, one for each direction. This example also demonstrates how the two layers can be combined to create three different images. By applying power through anode layer 10 an indicator pointing to the right appears. By applying power through anode layer 30 an indicator pointing to the left appears. By applying power through both anode layers 10, 30, a two-headed arrow appears. The intensity of an OLED emitter can be controlled by either changing the current to the device or by pulse-width modulation of the power, or a combination of the two. We can combine the color and multi-layer aspects of this embodiment with varying the intensity of the light from the areas corresponding to individual anode pattern elements to create a one- or two-headed arrow in either direction in which the shaft of the arrow is a color gradient that blends from the color of one OLED layer smoothly through to the color of the other layer.

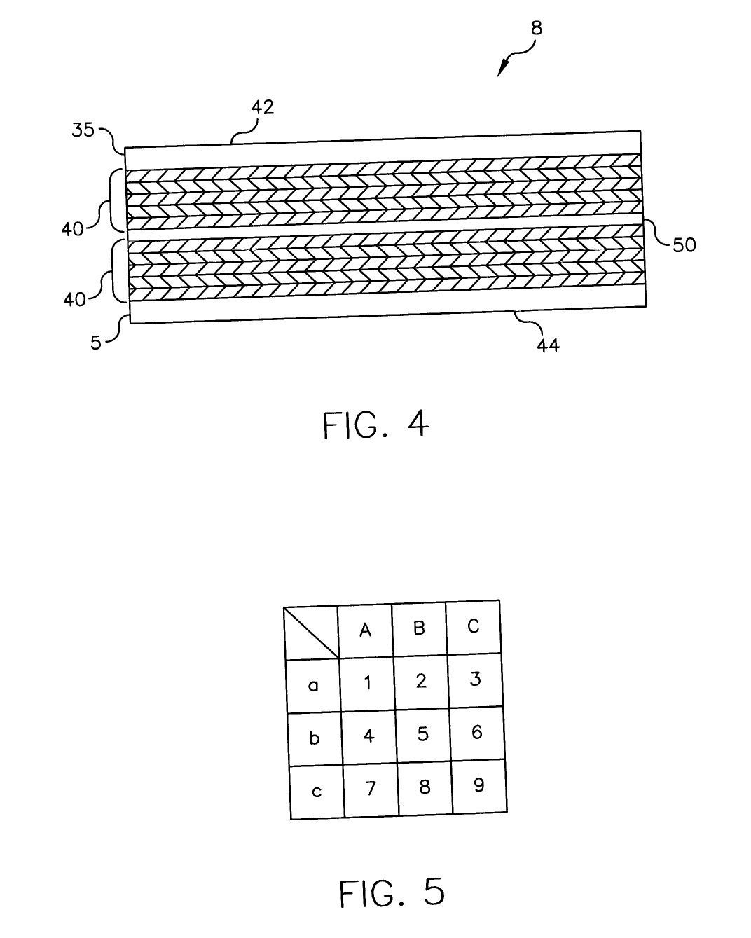

FIG. 4 shows an embodiment of a light-emitting sign 8 made in accordance with the present invention that is capable of displaying four or more distinct messages. This is achieved by interposing an insulating layer 50 between two dual-mode stacks 40 each stack 40 similar to that illustrated in FIG. 1. If the dual-mode stacks 40 are built using a transparent cathode layer and the insulating layer is transparent, then all the layers are visible from both sides. Each layer can contain a unique pattern, corresponding to a unique message. In other uses, each layer may contain a pattern element that can be combined with the elements in the other layers to produce 2ⁿ⁻¹ combinations. For this case, n=4 and the total possible combinations is 15. It should be obvious to one of ordinary skill in the art that this stacking procedure can be repeated to produce signs containing an arbitrary number of message layers. This number of layers need not be even, since half of the dual mode stack can be utilized. It is further obvious that by placing a reflective layer at one point in the stack, we can partition the number of messages between the two sides of the sign. As in the embodiment in FIG. 1, the dual-mode stack can be built with a pair of cathodes separated by an insulating layer instead of a common cathode. In addition, the order of the stack can be reversed so that the anode is in the center and may appear as a common anode, or as a pair of anodes separated by an insulating layer.

As shown in FIG. 3, and as is obvious to one of ordinary skill in the art, it is generally advantageous to carry electrical connections to the edge of the substrate 5 where they are exposed and available for use as electrical contacts for connectors or as solder/welding bond pads. A reduced number of contacts is often a design criterion because it can increase reliability and lower costs. For a multi-mode sign in which no two messages appear simultaneously, one can reduce the number of contacts by sharing them among the various anode and cathode layers. The table in FIG. 5 shows how the contacts of a nine-message sign with no common anodes or cathodes can be arranged to use 2*sqrt(9)=6 contacts. The numbers in the table correspond to the elements of a stack that correspond to a message. The lower case letters correspond to the anode contacts. The anodes of all entries in a row share the same contact. The upper-case letters correspond to cathode contacts. The cathodes of all entries in a column share the same cathode contact. By selecting a row and column, we select a specific message to appear. This process can be generalized to larger numbers of messages.

It is to be understood that various changes and modifications may be made without departing from the scope of the present invention, the present invention being limited by the claims that follow.

### PARTS LIST

5 Substrate
8 Sign
10 Anode layer 1
15 OLED layer 2
20 Common cathode
25 OLED layer 2
30 Anode layer 2
35 Cover
40 Dual-mode stack

42 Side
44 Side
45 Anode pattern element
50 Insulating layer

What is claimed is:

1. A multi-mode flat-panel light-emitting sign comprising:
a) a substrate;
b) a plurality of thin-film light-emitting structures located on said substrate, each structure comprised of an anode, a light-emitting layer, and a cathode wherein light-emitting layer has a pattern for providing a visual indicia when said light-emitting structure is activated, said anode and said cathode of each thin-film light-emitting structure being continuous over said substrate; and
c) a cover provided over said plurality of thin-film light-emitting structures.

2. The multi-mode flat-panel light-emitting sign of claim 1 where the plurality of thin-film light-emitting structures alternate in order.

3. The multi-mode flat-panel light-emitting sign of claim 1 where the adjacent cathode layers of two of said plurality thin-film light-emitting structures are merged into a common cathode.

4. The multi-mode flat-panel light-emitting sign of claim 1 where the anode layers of each of said plurality of thin-film light-emitting structures are patterned with a message or icon.

5. The multi-mode flat-panel light-emitting sign of claim 1 where the cathode layers of each of said plurality of thin-film light-emitting structures are patterned with a message or icon.

6. The multi-mode flat-panel light-emitting sign of claim 1 where the light-emitting layer is patterned with a message or icon.

7. The multi-mode flat-panel light-emitting sign of claim 1 where the light-emitting layer contains multiple regions, where each region emits a distinct color.

8. The multi-mode flat-panel light-emitting sign of claim 1 additionally comprised of a reflective layer between one pair of said plurality of thin-film light-emitting structures.

9. The multi-mode flat-panel light-emitting sign of claim 1 where the anode and/or cathode are comprised of a plurality of electrically independent regions, where each region has an externally available contact.

10. The multi-mode flat-panel light-emitting sign of claim 1 where multiple anodes share an external contact and where multiple cathodes share an electrical contact, chosen so that each of said plurality of light-emitting structures is independently controllable.

11. The multi-mode flat-panel light-emitting sign of claim 1 where the light-emitting layer comprises an organic light-emitting diode.

12. The multi-mode flat-panel light-emitting sign of claim 1 where the light-emitting layer contains multiple regions, and the intensity of light emitted by a region is controlled by varying current passed through the region.

13. The multi-mode flat-panel light-emitting sign of claim 1 where the light-emitting layer contains multiple regions, where the intensity of each of said light-emitting region is controlled by pulse width modulation.

14. The multi-mode flat-panel light-emitting sign of claim 1 where each of said plurality of thin-film light-emitting structures emits a distinct color.

15. The multi-mode flat-panel light-emitting sign of claim 1 where one of the anodes or cathodes of said plurality of thin-film light-emitting structures is reflective.

16. The multi-mode flat-panel light-emitting sign of claim 15 where the reflective anode or cathode is the top or bottom electrode.

17. The multi-mode flat-panel light-emitting sign of claim 1 where one or more of the possible messages is formed by illuminating a combination of said light-emitting layers.

18. A multi-mode flat-panel light-emitting sign comprising:
a) a substrate;
b) two thin-film light-emitting structures located on said substrate, each structure comprised of an anode, a light-emitting layer, and a cathode wherein either said anode and/or cathode has a continuous pattern for providing a visual indicia when said light-emitting structure is activated, said continuous pattern for each of said two thin-film light-emitting structures being electrically in common with each other, said thin-film light-emitting structures being continuous over said substrate; and
c) a cover provided over said two thin-film light-emitting structures.

19. The multi-mode flat-panel light-emitting sign of claim 18 where the two thin-film light-emitting structures alternate in order.

20. The multi-mode flat-panel light-emitting sign of claim 18 where the adjacent cathode layers of two of said two thin-film light-emitting structures are merged into a common cathode.

21. The multi-mode flat-panel light-emitting sign of claim 18 where the anode layers of each of said two of thin-film light-emitting structures are patterned with a message or icon.

22. The multi-mode flat-panel light-emitting sign of claim 18 where the cathode layers of each of said two of thin-film light-emitting structures are patterned with a message or icon.

23. The multi-mode flat-panel light-emitting sign of claim 18 where the light-emitting layer is patterned with a message or icon.

24. The multi-mode flat-panel light-emitting sign of claim 18 where the light-emitting layer contains multiple regions, where each region emits a distinct color.

25. The multi-mode flat-panel light-emitting sign of claim 18 additionally comprised of a reflective layer between one pair of said plurality of thin-film light-emitting structures.

26. The multi-mode flat-panel light-emitting sign of claim 18 where the anode and/or cathode are comprised of a plurality of electrically independent regions, where each region has an externally available contact.

27. The multi-mode flat-panel light-emitting sign of claim 18 where multiple anodes share an external contact and where multiple cathodes share an electrical contact, chosen so that each of said two light-emitting structures is independently controllable.

28. The multi-mode flat-panel light-emitting sign of claim 18 where the light-emitting layer comprises an organic light-emitting diode.

29. The multi-mode flat-panel light-emitting sign of claim 18 where the light-emitting layer contains multiple regions, and the intensity of light emitted by a region is controlled by varying current through the region.

30. The multi-mode flat-panel light-emitting sign of claim 18 where the light-emitting layer contains multiple regions, where the intensity of each of said light-emitting region is controlled by pulse width modulation.

31. The multi-mode flat-panel light-emitting sign of claim 18 where each of said two of thin-film light-emitting structures emits a distinct color.

32. The multi-mode flat-panel light-emitting sign of claim 18 where one of the anodes or cathodes of said two of thin-film light-emitting structures is reflective.

33. The multi-mode flat-panel light-emitting sign of claim 32 where the reflective anode or cathode is the top or bottom electrode.

34. The multi-mode flat-panel light-emitting sign of claim 18 where one or more of the possible messages is formed by illuminating a combination of said light-emitting layers.
